(19) United States
(12) Patent Application Publication
(10) Pub. No.: US 2018/0309445 A1
(43) Pub. Date: Oct. 25, 2018

(54) CAPACITIVE TOUCH SENSOR PANEL AND METHOD OF MAKING THE SAME

(71) Applicant: Alexander LIPKOVICH, Bat Yam (IL)

(72) Inventor: Alexander LIPKOVICH, Bat Yam (IL)

(21) Appl. No.: 15/764,278

(22) PCT Filed: Dec. 5, 2016
(86) PCT No.: PCT/IL2016/051298

§ 371 Date: Mar. 28, 2018

(30) Foreign Application Priority Data
Jan. 11, 2016 (IL) 243554

(51) Int. Cl. H03K 17/96; G06F 3/044; G06F 3/0354

(52) U.S. Cl. CPC H03K 17/9622; G06F 3/044; H03K 2017/9615; H03K 2217/96077; G06F 3/03547

(57) ABSTRACT

A capacitive touch sensor panel of present invention includes a metal panel with a plurality of electrically isolated and separated metal buttons. A capacitive touch sensor also includes a dielectric layer attached to the backend of said metal panel and to the backend of said metal buttons, and a circuit bearing structure attached to said metal panel and having a plurality of sensor pads located directly beneath said metal buttons, and wherein the circuit bearing structure has a capacitive coupling between each of the sensor pads and the grounded parts of said circuit bearing structure.

### BACKGROUND OF THE INVENTION

### Technical Field

The present disclosure generally relates to user input mechanisms, and more particularly, to any type of input device having at least one capacitive touch button.

### Description of the Related Art

Buildings and many other man-made structures often include elevators, doors and gates with a button panel as part of a user interface that controls these access points and structures. These interfaces may often rely on using capacitive touch type buttons, or on more conventional, positive pressure type buttons.

FIG. 1 illustrates a prior art capacitive touch sensor panel 100. The prior art capacitive touch sensor panel 100 includes a top dielectric layer 101 with printed buttons (not shown) and a printed circuit board (PCB) 102 with sensor pads located directly beneath the printed buttons. The prior art panel 100 also comprises a microcontroller (not shown) that continuously measures the capacitive coupling between each of the sensor pads and the ground 104 (such as a capacitive coupling 105). When a user's finger 107 touches one of the buttons on the dielectric layer 101, the microcontroller detects an additional capacitive coupling 106 that is created between a sensor pad 103 (located beneath the button) and the ground 104.

This touch panel design is not durable enough however, as the top dielectric layer 101 is usually made of plastic material that could be easily damaged by vandals.

Another prior art touch sensor is disclosed in U.S. Patent Application No. 2011/0057889. The sensor disclosed in U.S. Patent Application No. 2011/0057889 includes a first electrode layer with a first force sensor electrode, a second force sensor electrode positioned in a second electrode layer or on a support layer, and a dielectric substrate at least a portion of which is compressible and is positioned between the first and second force sensor electrodes.

FIG. 2 illustrates a prior art deflection based touch sensor panel 200. The sensor panel 200 comprises a top layer 201 having a flexible sensor area 205 made of thin metal. Upon touching by finger 204, the sensor area 205 is deflected and this deflection is detected by a deflection sensor 203 located on a PCB 202. The deflection sensor 203 may be a piezoelectric, or capacitive, or inductive sensor.

The deflection based touch sensor panel is more complicated than a capacitive touch sensor panel, has a shorter life span (as it includes moving parts), more expensive to produce, and less user friendly (as it requires a more forceful touch by a finger).

Accordingly, there is a need in the art to address the foregoing issues and thereby provide a more durable, less complicated, and more vandal resistant design for a touch sensor panel.

### SUMMARY OF THE INVENTION

In accordance with an aspect of the present disclosure, a capacitive touch sensor panel is disclosed.

According to an embodiment of present invention, the capacitive touch sensor panel includes a metal panel having a plurality of electrically isolated and separated metal buttons, a dielectric layer attached to the backend of said metal panel and to the backend of said metal buttons, and a circuit bearing structure attached to said metal panel and having a plurality of sensor pads located directly beneath said metal buttons, and wherein the circuit bearing structure has a capacitive coupling between each of the sensor pads and the grounded parts of said circuit bearing structure.

According to another embodiment of the present invention, the capacitive touch sensor panel includes a metal panel having a plurality of electrically isolated and separated illuminated metal buttons, a molded, optically transparent, dielectric layer attached to the backend of said metal panel and to the backend of said metal buttons, and a circuit bearing structure attached to said metal panel and having a plurality of sensor pads located directly beneath said metal buttons, and wherein the circuit bearing structure has a capacitive coupling between each of the sensor pads and the grounded parts of said circuit bearing structure, and wherein said metal buttons include at least one mechanical support per button, said mechanical support is abutting to the circuit bearing structure.

In accordance with another aspect of the present disclosure, a method is disclosed. According to an exemplary embodiment, the method includes attaching a dielectric layer to the backend of a metal panel, creating separated and electrically isolated metal buttons from the metal panel, and attaching a prechosen and appropriate circuit bearing structure to the metal panel.

The aforementioned summary of preferred and exemplary embodiments of the present disclosure is merely illustrative of the inventive concepts presented herein, and is not intended to limit the scope of the present disclosure in any manner.

### BRIEF DESCRIPTION OF THE DRAWINGS

The above-mentioned and other features and advantages of this disclosure, and the manner of attaining them, will become more apparent and the disclosure will be better understood by reference to the following description of embodiments of the disclosure taken in conjunction with the accompanying drawings, wherein:

FIG. 1 shows a prior art capacitive touch sensor panel;

FIG. 2 shows a prior art deflection based touch sensor panel;

FIG. 3A and FIG. 3B show a capacitive touch sensor panel according to the exemplary embodiments of the present disclosure;

FIG. 4A shows a front side of the capacitive touch sensor panel according to an embodiment of the present disclosure;

FIG. 4B shows a back side of a metal panel of the capacitive touch sensor panel, according to an embodiment of the present disclosure;

FIG. 4C shows a PCB attached to a back side of a metal panel of the capacitive touch sensor panel, according to an embodiment of the present disclosure.

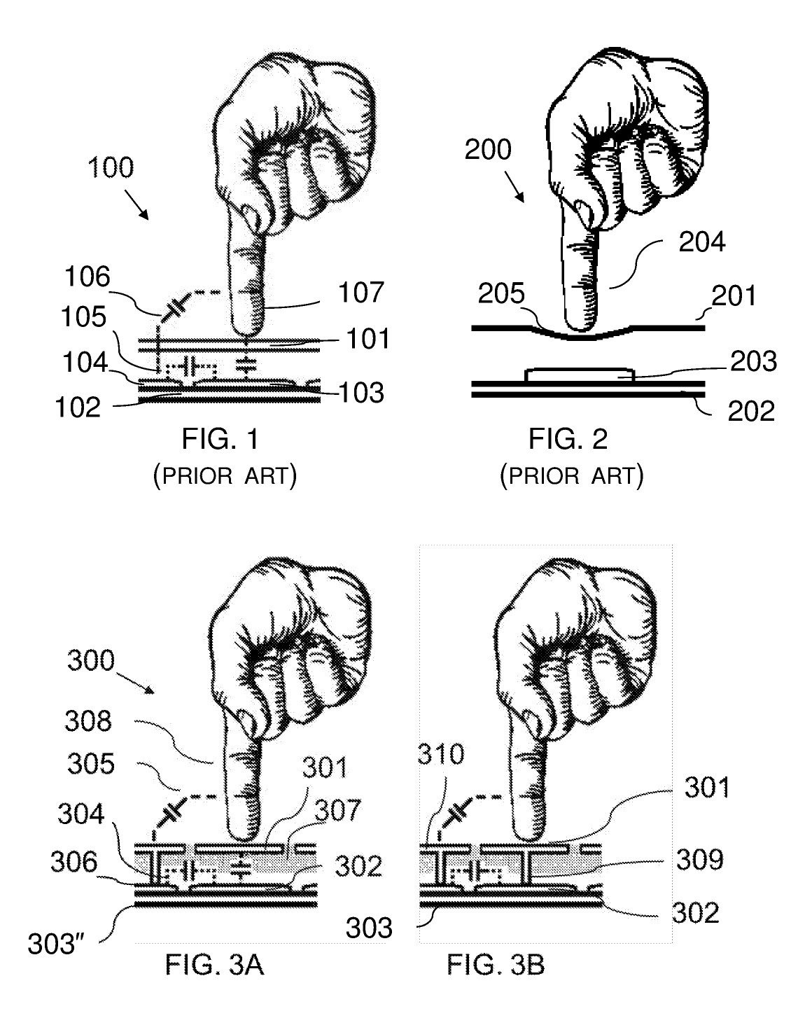

The exemplifications set out herein illustrate preferred embodiments of the disclosure, and such exemplifications are not to be construed as limiting the scope of the disclosure in any manner.

### DETAILED DESCRIPTION OF THE PREFERRED EMBODIMENTS

For a better understanding of the invention and to show how the same may be carried into effect, reference will now be made, purely by way of example, to the accompanying drawings. With specific reference to the drawings in detail, it is stressed that the particulars shown are by way of example and for purposes of illustrative discussion of preferred embodiments of the present invention only, and are presented for the purpose of providing what is believed to be the most useful and readily understood description of the principles and conceptual aspects of the invention. In this regard, no attempt is made to show structural details of the invention in more detail than is necessary for a fundamental understanding of the invention. From the description taken together with the drawings it will be apparent to those skilled in the art how the several forms of the invention may be embodied in practice. Moreover, it is to be understood that the phraseology and terminology employed herein is for the purpose of description and should not be regarded as limiting the scope of the invention hereof.

FIG. 3A and FIG. 3B illustrate a schematic structure of a capacitive touch sensor panel 300 according to an embodiment of the present invention. The capacitive touch sensor panel 300 includes a plurality of metal buttons 301 which are mechanically supported and held in their place by a dielectric material 307. The metal buttons 301 are also mechanically attached or bonded by the dielectric material 307 to a grounded metal panel part 310 that surrounds the metal buttons 301.

The metal buttons 301 may also comprise one or more mechanical supports 309 that provide additional stability to the metal buttons 301 by abutting them to a circuit bearing structure 303, such as a printed circuit board (PCB) 303′, thus preventing damage to the buttons 301 that may be caused by an excessive force from a user.

The capacitive touch sensor panel 300 also comprises a microcontroller (not shown) that continuously measures the capacitive coupling (such as a capacitive coupling 304) between each of the sensor pads 302 of the PCB 303′ and the grounded part 306 of the PCB 303′. When a user's finger 308 touches one of the metal buttons 301, the microcontroller detects an additional capacitive coupling 305 that is created between the sensor pad 302 (located on the PCB 303′, beneath the button 301) and the grounded part 306 of the PCB 303′.

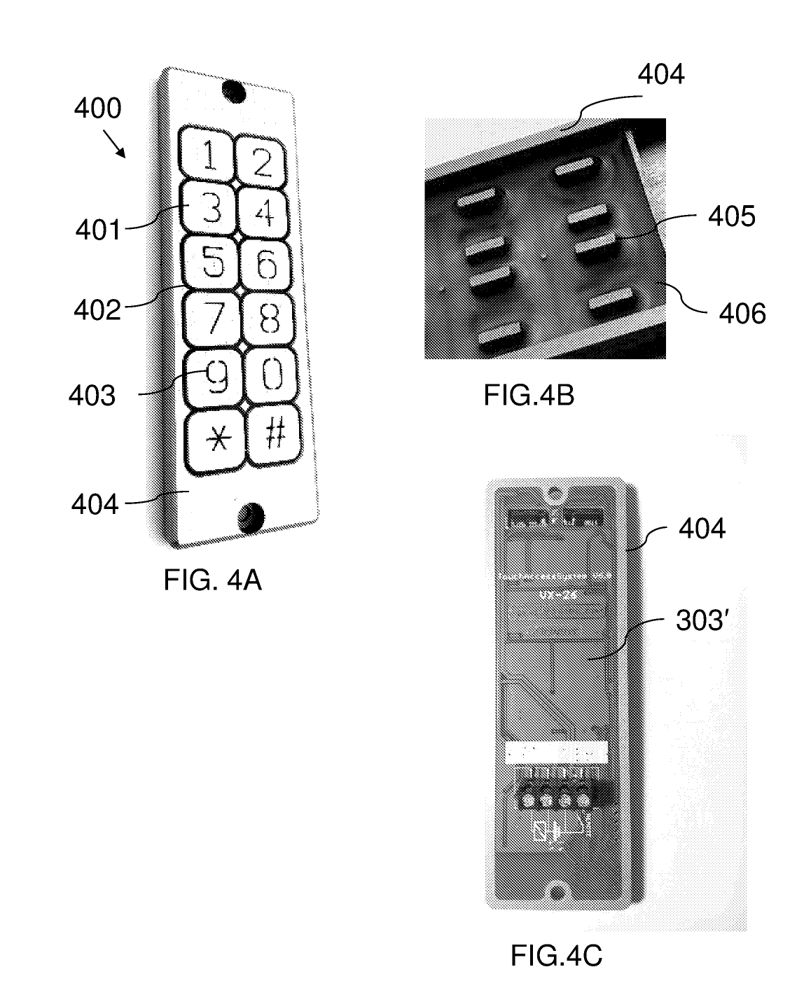

FIG. 4A illustrates a front side of a capacitive touch sensor panel 400 according to an embodiment of the present invention. The capacitive touch sensor panel 400 comprises a metal panel 404 with a plurality of metal buttons 401 separated from each other and from the panel 404 by a groove 402.

FIG. 4B shows the backside of the metal panel 404. The backside of the metal panel 404 contains a dielectric material 406 that provides a mechanical support for buttons 401. The dielectric material 406 may be a polymer, such as epoxy, acryl, silicone or any other liquid polymer that is molded into the backside of the metal panel 404 and then hardened. Alternatively, the dielectric material 406 may be comprised of a solid material, mechanically attached to the backside of the metal panel 404. The dielectric material 406 may be optically transparent or diffusive material in order to illuminate the metal buttons 401 through an engraved button symbol 403.

The metal buttons 401 may additionally include one or more mechanical supports 405 for each button. The mechanical support 405 provides an additional strength to the metal buttons 401 and also increases the adhesion surface between the buttons 401 and the dielectric material 406.

In many embodiments of the present invention, the circuit bearing structure 303 of the capacitive touch sensor panel 300 might be a flexible printed circuit 303″, a PCB 303′, or any other suitable component or structure having conductive circuit patterns affixed thereto.

The capacitive touch sensor panel according to an embodiment of the present invention is manufactured as follows: first a dielectric material is attached to the backend of a metal panel, then the buttons are either etched or machined, starting from the front surface of the metal panel, until they are separated and there is no electrical contact between them. In a final stage, the metal panel is attached to the appropriate printed circuit and the sensor panel is ready to use.

As described above, the present disclosure provides an improved design for a capacitive touch sensor panel. The present design of a capacitive touch sensor panel is more durable and has a longer life span, as it made of metal and it does not contain moving parts. Furthermore, the present design is more environmentally friendly, as fewer devices are discarded (and therefore fewer are manufactured) due to the inherent improved durability of the disclosed sensor panel.

While this disclosure has been described as having a preferred design, the present embodiments can be further modified within the scope of this disclosure. This application is therefore intended to cover any variations, uses, or adaptations of the embodiments using their general principles. Further, this application is intended to cover such departures from the present disclosure as come within known or customary practice in the art to which this disclosure pertains and which fall within the limits of the appended claims.

1. A capacitive touch sensor panel, manufactured by a process comprises the steps of:
i. providing a metal panel, wherein an exterior front surface thereof configured to be used as said touch sensor panel;
ii. attaching a dielectric layer to the backend of a said metal panel; and
iii. separating and thereby creating separated and electrically isolated individual metal buttons from said front surface of said metal panel, subsequently to said attaching of said dielectric layer; and
iv. attaching an appropriate electronic circuit bearing structure to said metal panel; wherein said capacitive touch sensor panel resulting aforesaid steps comprising:
a) said metal panel having a plurality of said electrically isolated and metal buttons, characterized by that said electrically isolated buttons have been separated from said front surface of said metal panel, after said attaching of said dielectric layer;
b) said dielectric layer attached to said backend of said metal panel and to a backend of said individual metal buttons; and
c) said electronic circuit bearing structure attached to said metal panel and having a plurality of sensor pads located directly beneath said individual metal buttons, wherein said electronic circuit bearing structure comprises a capacitive coupling between each of said sensor pads and at least one grounded part of said circuit bearing structure.

2. The capacitive touch sensor panel of claim 1, wherein said circuit bearing structure is a printed circuit board.

3. The capacitive touch sensor panel of claim 1, wherein said circuit bearing structure is a flexible printed circuit.

4. The capacitive touch sensor panel of claim 1, wherein said metal buttons include at least one mechanical support per button, said mechanical support is abutting to said printed circuit.

5. The capacitive touch sensor panel of claim 4, wherein said dielectric layer is a molded layer.

6. The capacitive touch sensor panel, of claim 5, further comprises an illumination means, wherein said metal buttons are illuminated buttons.

7. A method of manufacturing a capacitive touch sensor panel, said method comprises:
i. providing a metal panel, wherein an exterior front surface thereof configured to be used as said touch sensor panel;
ii. attaching a dielectric layer to the backend of said metal panel;
iii. separating and thereby electrically isolating individual metal buttons from said front surface of said metal panel, subsequently to said attaching of said dielectric layer; and
iv. attaching an appropriate electronic circuit bearing structure to said metal panel.

8. The method of manufacturing a capacitive touch sensor panel, as in claim 7, wherein said separating comprises at least one member selected from the group consisting of: etching around said individual metal buttons and machining around said individual metal buttons.

9. The method of manufacturing a capacitive touch sensor panel, as in claim 7, wherein said circuit bearing structure is a printed circuit board.

10. The method of manufacturing a capacitive touch sensor panel, as in claim 7, wherein said circuit bearing structure is a flexible printed circuit.

11. The method of manufacturing a capacitive touch sensor panel, as in claim 7, wherein said metal buttons include at least one mechanical support per button, said mechanical support is abutting to the printed circuit.

12. The method of manufacturing a capacitive touch sensor panel, as in claim 7, wherein said attaching of said dielectric layer comprises molding a dielectric layer.

13. The method of manufacturing a capacitive touch sensor panel, as in claim 7, further comprises incorporating at least one an illumination means into said panel, configured to illuminate said dielectric layer around said buttons.
